(19) United States
(12) Patent Application Publication
(10) Pub. No.: US 2007/0252478 A1
(43) Pub. Date: Nov. 1, 2007

(54) Solid-State Actuator, Especially Piezoceramic Actuator

(76) Inventors: Karl Lubitz, Ottobrunn (DE); Thorsten Steinkopff, Egmating (DE)

Correspondence Address: HARNESS, DICKEY & PIERCE, P.L.C., P.O.BOX 8910, RESTON, VA, 20195, US

(21) Appl. No.: 11/664,099

(22) PCT Filed: Aug. 2, 2005
(86) PCT No.: PCT/EP05/53752

§ 371 Date: Mar. 29, 2007

(30) Foreign Application Priority Data
Sep. 30, 2004 (DE) 10 2004 047 696.9

(51) Int. Cl. H01L 41/083; H01L 41/187; H02N 2/00

(52) U.S. Cl. 310/330; 310/358; 310/363; 310/364; 310/365

(57) ABSTRACT

An embodiment of the invention relates to a solid-state actuator, especially a piezoceramic actuator, which comprises a support layer to which at least one actuator layer, especially a piezoceramic layer, is applied, the actuator layer being disposed between contact electrodes. In order to avoid a creep behaviour of the solid-state actuator, the resistivity of the actuator layer is rated between 110⁸ Ωm to 110¹⁰ Ωm and/or an actuator control device for applying a control voltage to the contact electrodes is provided and the maximum control voltage is selected in such a manner that the maximum mechanical voltage in the solid-state actuator is below the coercive voltage.

### PRIORITY STATEMENT

This application is the national phase under 35 U.S.C. § 371 of PCT International Application No. PCT/EP2005/053752 which has an International filing date of August 2, 2005, which designated the United States of America and which claims priority on German Patent Application number 10 2004 047 696.9 filed Sep. 30, 2004, the entire contents of which are hereby incorporated herein by reference.

### FIELD

Embodiments of the invention generally relate to a solid-state actuator, in particular a piezoceramic actuator. For example, they may relate to one having a substrate on which at least one actuator layer, in particular a piezoceramic layer, is deposited, the actuator layer being disposed between contact electrodes.

### BACKGROUND

Solid-state actuators and, in particular, piezoceramic actuators are known which, in the simplest case, include a composite of an actuator material and a substrate or of a plurality of e.g. attached disks of piezoceramic material. By depositing contact electrodes bilaterally on the actuator layer or layers and applying a voltage to the contact electrodes, an electric field can be set up between them, so that an electric field acts on the piezoceramic material, causing the piezoelectric material to change in length.

The solid-state actuator can be implemented, for example, as a piezoelectric bending-mode transducer. With this composite, termed a bimorph in the simplest case, the piezoceramic actuator layer is disposed on a non-piezoelectric, i.e. undriven substrate, the actuator layer generally being produced from a PZT ceramic, i.e. doped lead zirconate titanate. Bending-mode transducers are usually clamped at one end, the force or displacement produced at the free end of the solid-state actuator being used as the actuatory property. If the bending-mode transducer is driven in the thickness direction with an electric field, the transducer contracts in its transverse direction, causing its tip to be displaced in the direction of the actuator layer.

Other piezoelectric bending-mode transducers are also known which may differ in terms of design, type of construction, selection of substrate material and other criteria. Solid-state actuators known as trimorphs typically include a substrate sandwiched between two piezoelectric actuator layers which are e.g. driven alternately. Also known are multilayer bending-mode transducers which have no substrate and include a plurality of piezoceramic actuator layers alone. With the latter, only one half is electrically driven in order to produce a deflection.

The common feature of the above-described bending-mode transducers is that, after rapid electrical driving via the contact electrodes, they exhibit an immediate actuator response over time determined by the resonance frequency, but then additionally show pronounced creep behavior so that the displacement or rather the force continues to increase over a long period, the amount of subsequent creep possibly amounting to up to 20% of the total displacement of the bending-mode transducer. The creep may last for hours or even days depending on the drive applied. This has the disadvantage in practice that the creep occurring when an electrical voltage is applied to or disconnected from the contact electrodes must be allowed for as an additional tolerance. Only the brief, immediate actuator stroke without additional creep is therefore used as the usable displacement or power stroke.

### SUMMARY

At least one embodiment of the present invention includes a solid-state actuator which does not have at least one of the abovementioned disadvantages, or at least only to a reduced extent.

According to a variant of at least one embodiment of the invention, it has surprisingly emerged that the creep phenomenon can be significantly reduced if the electrical conductivity of the material constituting the actuator layer is increased compared to that of the materials normally used such as lead zirconate titanate (PZT), i.e. the resistivity is reduced. According to at least one embodiment of the invention the resistivity of such an actuator layer which is implemented in particular as a piezoceramic layer is in the order of 1·10⁸ to 1·10¹⁰ Ωm. The resistivity of an actuator layer according to the invention is therefore a few powers of ten less than the resistivity for a typical piezoceramic layer. For example, the resistivity of soft PZT is approximately 1·10¹² Ωm.

The advantage that can be achieved by increasing the resistivity is that the achievable stroke or displacement of a conventional solid-state actuator including the displacement achievable by the creep process can be realized in a considerably shorter time. In other words, with the solid-state actuator according to at least one embodiment of the invention—compared to existing solid-state actuators—the same displacement can be achieved in a shorter time, so that the solid-state actuator can be operated at higher clock rates. The consequence of this is that, one the one hand, not only the brief stroke without the additional creep process, but the physically possible stroke of the solid-state actuator can be used as the usable displacement or power stroke. This simplifies the driving of the solid-state actuator, as the creep occurring when an electrical voltage is applied or removed now no longer needs to be allowed for as an additional tolerance.

The same advantages can be achieved with a second variant of a solid-state actuator according to at least one embodiment of the invention, wherein an actuator driving means for applying a drive voltage to the contact electrodes is provided and wherein the maximum drive voltage is selected such that, in the solid-state actuator, the maximum mechanical voltage is less than the coercive voltage. For the piezoceramic materials generally used, the mechanical voltages are in the region of the so-called coercive voltage values at which maximum domain switching occurs under the effect of the mechanical voltages. This is known as “ferroelastic behavior”. This second variant is based on the surprising recognition that creep is caused at least in part by domain switching or ferroelastic processes in those regions of the bender in which the mechanical voltages attain the coercive voltage level. The mechanical voltages are known to vary along the thickness of an actuator layer, whereas they are constant it its longitudinal direction. The domain switching processes are nucleation and nucleus growth processes and are characterized by a certain time requirement. The activity, i.e. the bending, of the solid-state actuator is not delayed by avoiding ferroelastic domain switching.

The above-described advantages of at least one embodiment of the invention can also be achieved by a solid-state actuator according to at least one embodiment of the invention in which the features described in connection with the first and second variant are combined together. Accordingly the inventive solid-state actuator according to at least one embodiment of the third variant is characterized in that the resistivity of the actuator layer is in the order of 1·10⁸ to 1·10¹⁰ Ωm and an actuator driving device for applying a drive voltage to the contact electrodes is provided and the maximum drive voltage is selected such that, in the solid-state actuator, the maximum mechanical voltage is less than the coercive voltage.

A solid-state actuator provided with the above features constitutes, in an example embodiment, a piezoelectric bending-mode transducer disposed with one end on or in a fixing device, so that only the other end is subject to displacement.

In another embodiment of the invention, the relationship between the drive voltage and the mechanical voltage in the solid-state actuator is determined by a calculation or is stored in a table, e.g. in the actuator driving device.

Increasing the electrical conductivity of the actuator layer material can be achieved as claimed in one embodiment of the invention by additionally doping the actuator material with mono-, di-, or trivalent cations. Lead zirconate titanate is the preferred actuator starting material. In one embodiment, the monovalent cations on the A-site of the perovskite cell result in acceptor doping. In another embodiment, the di- or trivalent cations on the B-site of the perovskite cell also result in acceptor doping. Also conceivable is a combination of the two specified acceptor doping possibilities.

In a further embodiment, the solid-state actuator is implemented as a so-called trimorph in which the substrate is disposed between two actuator layers.

In a further advantageous embodiment, the substrate is implemented as an actuator layer, in particular a piezoceramic layer, so that the solid-state actuator constitutes a multilayer actuator including at least two actuator layers.

In another embodiment, the solid-state actuator can have a plurality of actuator layers for implementing a multilayer actuator, the contact electrodes disposed inside the layer stack likewise being driven by the driving device to create equipotential surfaces. The electrically highly conductive electrodes disposed inside the layer stack are preferably made of silver or a silver alloy, acting as equipotential surfaces so that they compensate a significant part of the electric field distribution by means of corresponding charges. In addition, the silver of the electrodes diffuses into the adjacent piezoceramic actuator layers, which means that further free charge carriers are present in the ceramic so that the conductivity is advantageously increased still further. This effect is particularly marked because of the presence of a large number of electrodes. Compared to the prior art solid-state actuators used hitherto, a multilayer actuator implemented in this way has the same advantages as those described in the introduction. In particular, a. significant reduction in creep is to be observed.

In one embodiment, the actuator layers of the multilayer actuator have a thickness ranging from 10 to 30 μm, in particular 20 μm. A multilayer actuator with actuator layers of the specified layer thickness has a total thickness no different from that of the known multilayer actuators. In other words, this therefore means that a multilayer actuator according to at least one embodiment of the invention has a correspondingly larger number of actuator layers, as the thickness of conventional actuator layers is in the region of 80 μm and above.

### BRIEF DESCRIPTION OF THE DRAWINGS

Further features of the solid-state actuator according to embodiments of the invention will now be explained in greater detail with reference to the accompanying drawings in which:

FIG. 1 shows a solid-state actuator according to the invention, implemented as a bimorph bending-mode transducer,

FIG. 2 shows a diagram illustrating the length variation of the layers of the solid-state actuator shown in FIG. 1 along the z-axis,

FIG. 3 shows a diagram illustrating the mechanical voltage along the z-axis of the solid-state actuator shown in FIG. 1,

FIG. 4 shows a diagram illustrating the displacement of a solid-state actuator in response to a drive signal for different electrical conductivities of the actuator layer of the solid-state actuator,

FIG. 5 shows a diagram illustrating solid-state actuator drive according to an embodiment of the invention, and

FIG. 6 shows a multilayer actuator according to an embodiment of the invention compared to a multilayer actuator known from the prior art.

### DETAILED DESCRIPTION OF THE EXAMPLE EMBODIMENTS

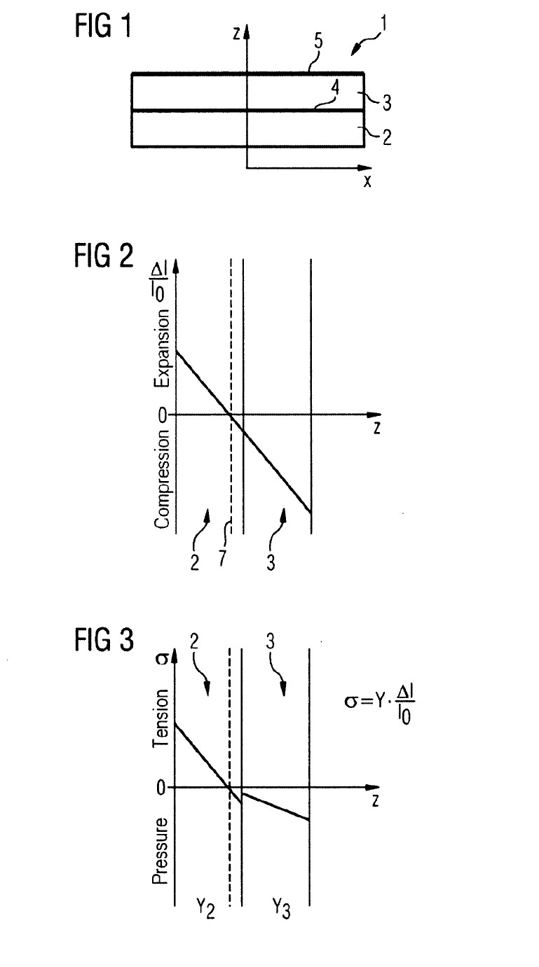

FIG. 1 shows a solid-state actuator according to an embodiment of the invention 1 in cross section. It includes a substrate 2 made of an electrically insulating material and, deposited thereon, an actuator layer 3 made of a piezoceramic material, e.g. lead zirconate titanate. On both sides of the actuator layer 3 there are disposed contact electrodes 4, 5 to which an electrical voltage can be applied so as to produce an electric field between the contact electrodes 4, 5. The mechanical design of the solid-state actuator 1 according to an embodiment of the invention does not differ in principle from known solid-state actuators. To avoid pronounced creep behavior when the electrical voltage is applied or disconnected, changes compared to known arrangements are made to the piezoceramic material and alternatively or additionally to the drive of the solid-state actuator 1.

Applying a voltage to the contact electrodes 4, 5 causes the actuator layer 3 to expand along its z-axis, while in the x-direction a contraction occurs, so that the solid-state actuator bends upward. The length variation Δl/l₀ taking place inside the substrate and the actuator layer 3 is shown in FIG. 2. While the substrate 2 undergoes expansion until it reaches the so-called neutral phase 7, the actuator layer 3 is compressed. As the material properties of the substrate 2 and the actuator layer 3 are different, the mechanical voltage undergoes a step change at the zero crossing point.

According to the equation

$$σ = Y \cdot \frac{Δ l}{{l}_{0}}$$

shown in FIG. 3, tension is applied to most of the region of the substrate 2, with compression being exerted inside the actuator layer 3. Because of different Young's moduli y2 and y3 respectively, there is produced at the transition between the substrate 2 and the actuator layer 3 a discontinuity in the compressive load which is also reflected in a changed gradient.

Over the z-axis there is therefore produced an inhomogeneous mechanical voltage resulting in an inhomogeneous distribution of the electric field in the actuator layer 3. When a voltage is applied to the contact electrodes 4, 5 there is therefore produced inside the actuator layer 3, not a constant, homogeneous electric field, but a linear field dependency with parabolic potential distribution. To bring about a state of equilibrium, charges must therefore flow inside the actuator layer, it having been shown that the part of the creep attributable to charge equalization can be reduced by using, instead of a maximally insulating piezoceramic according to the prior art, a ceramic with higher but defined conductivity.

Further experiments have shown that a resistivity of the actuator layer 3 in the order of 1·10⁸ to 1·10¹⁰ Ωm allows a sufficiently rapid charge equalization so that the creep of the bending-mode transducer 1 from FIG. 1 can be virtually eliminated. The increase in the electrical conductivity of the actuator layer by several powers of ten can be achieved in the known manner by slight acceptor doping in the actuator layer material, while leaving the other piezoelectric properties unimpaired. Lead zirconate titanate in which monovalent cations such as sodium, copper or silver are doped on the A-site of the perovskite cell, or alternatively or additionally di- or trivalent cations such as chromium, iron or manganese are doped on the B-site, continues to be a suitable starting material for the actuator layer.

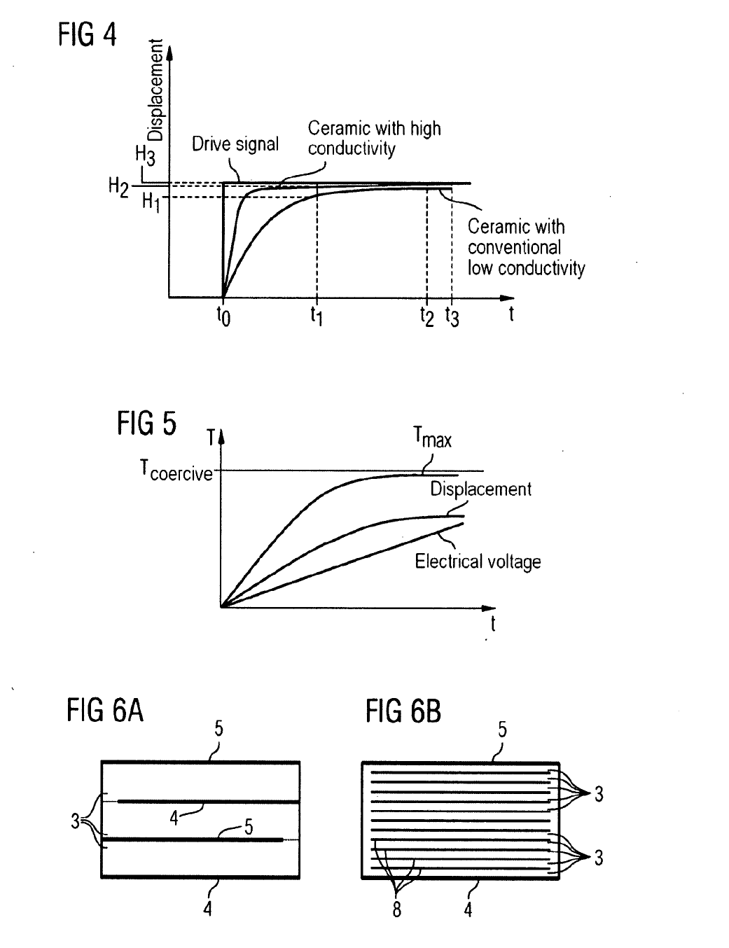

The effects of different actuator layer conductivities are shown in FIG. 4. At a time t₀ a voltage is applied to the contact electrodes 4, 5 of the solid-state actuator 1, causing a displacement of the bending-mode transducer. An actuator layer (ceramic) with low conductivity produces the least displacement. A ceramic with low conductivity, like the prior art piezoelectric ceramics, achieves at time t₁ a stroke H₁ which now asymptotically approaches a final value H₃, the increase in the displacement beyond the value H₁ being termed the creep behavior. The displacement H₂ is attained at time t₃. The maximum possible displacement H₃ can only be achieved if the drive signal retains its value shown in the figure. In contrast, a ceramic with high conductivity according to an embodiment of the invention exhibits displacement H₃ at time t₁. The further possible displacement between H₂ and H₃ is irrelevant for practical purposes.

The illustration shows that a bending-mode transducer can achieve a significantly higher displacement within the same time or alternatively can be clocked in less time for a required displacement.

With additional free charge carriers in the actuator layer the creep effect of a solid-state actuator can therefore be reduced. However, creep can also be influenced by another effect known as domain switching. Domain switching, i.e. the change in direction of elementary dipoles can be caused both electrically and mechanically, the maximum possible mechanical voltage Tₘₐₓ in the case of conventional piezoceramic layers being in the region of the so-called coercive voltage values at which maximum domain switching occurs under the effect of the mechanical voltages. This is termed ferroelastic behavior. To avoid the effect of domain switching the drive voltage is therefore limited such that in a driven solid-state actuator the maximum mechanical voltages remain well below the coercive voltages (FIG. 5). Corresponding information can be obtained via a calculation or stored values in an actuator driving device. Also conceivable is the use of other piezoactuators which already exhibit a higher coercive voltage because of their material properties, materials with a coercive voltage higher than 25 MPa being suitable for this purpose.

If the solid-state actuator is implemented as a multilayer actuator, the creep behavior can already be achieved by a modified physical structure. FIG. 6a shows a multilayer actuator (comprised of three layers 3) of the type known from the prior art, each of the actuator layers 3 having a layer thickness of approximately 80 μm or more. A drive signal is likewise applied to the electrodes disposed in the layer stack by the actuator driving device.

In contrast, FIG. 6b shows a multilayer actuator according to an embodiment of the invention wherein the layer thicknesses of the particular actuator layers 3 range from 10 to 30 μm, preferably 20 μm. The electrodes inside the layer stack are driven by the actuator driving device and have a connection to the contact electrodes 4, 5 on the exterior of the multilayer actuator. The electrodes inside the multilayer actuator, which are preferably made of silver or a silver alloy, therefore constitute equipotential surfaces which can compensate the majority of the electric field distribution by corresponding charges. In addition, the silver of the electrodes diffuses into the adjacent piezoceramic actuator layers, which means that further free charge carriers are present in the ceramic so that the conductivity is advantageously increased still further. This effect is particularly pronounced because of the presence of a large number of electrodes. This ensures that the creep behavior is improved. The creep behavior can be optimized still further by combining this with the above-described improvements.

### EXAMPLE

The inventive considerations of at least one embodiment will now be made clear once more with reference to a typical bending-mode transducer. A bending-mode transducer includes two piezoceramic layers (44×7.2×0.26 mm³) deposited on both sides of an insulating substrate. If 200 V are applied to one of the actuator layers, at a resistivity of 1·10¹² Ωm typical for soft PZT, a current of 0.24 nA flows. The time constant for internal charge reversal processes ranges from 1 to 1000 seconds. If the resistivity of the ceramic material is reduced by three powers of ten by way of appropriate doping, the time constant responsible for the creep drops to the milliseconds or seconds range. At the same time the steady-state current of the bending-mode transducer remains well below the limit value of 1 pA.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A solid-state actuator comprising:
a substrate; and
at least one actuator layer, applied to the substrate, the at least one actuator layer being disposed between contact electrodes, a
resistivity of the actuator layer being in an order of 1·10⁸ to 1·10¹⁰ Ωm.

2. A solid-state actuator, comprising:
a substrate;
at least one actuator layer, applied to the substrate, the at least one actuator layer being disposed between contact electrodes; and
actuator driving means for applying a drive voltage to the contact electrodes, a maximum drive voltage being selected such that, in the solid-state actuator, a maximum mechanical voltage is less than a coercive voltage.

3. A solid-state actuator, comprising:
a substrate;
at least one actuator layer, applied to the substrate, the at least one actuator layer being disposed between contact electrodes,
resistivity of the at least one actuator layer being in an order of 1·10⁸ to 1·10¹⁰ Ωm; and
actuator driving means for applying a drive voltage to the contact electrodes, a maximum drive voltage being selected such that, in the solid-state actuator, a maximum mechanical voltage is less than a coercive voltage.

4. The solid-state actuator as claimed in claims 2, wherein the relationship between the drive voltage and the mechanical voltage in the solid-state actuator is at least one of stored in a table and determined by a calculation.

5. The solid-state actuator as claimed in claim 1, wherein the at least one actuator layer is made of lead zirconate titanate and is additionally doped with at least one of mono-, di- and trivalent cations.

6. The solid-state actuator as claimed in claim 5 , wherein the monovalent cations are implanted in the A-site of the perovskite cell and produce an acceptor doping.

7. The solid-state actuator as claimed in claim 5, wherein the di- or trivalent cations are implanted in the B-site of the perovskite cell and produce an acceptor doping.

8. The solid-state actuator as claimed in claim 1, wherein the substrate is disposed between two actuator layers.

9. The solid-state actuator as claimed in claim 1, wherein the substrate is implemented as an actuator layer.

10. The solid-state actuator as claimed in claim 1, wherein the solid-state actuator includes a plurality of actuator layers for implementing a multilayer actuator and contact electrodes, disposed inside a layer stack, are driven by an actuator driver to create equipotential surfaces.

11. The solid-state actuator as claimed in claim 10, wherein the actuator layers of the multilayer actuator have a thickness ranging from 10 to 30Ωm.

12. The solid-state actuator as claimed in claim 1, wherein the solid-state actuator -constitutes a piezoelectric bending-mode transducer.

13. The solid-state actuator as claimed in claim 1, wherein the solid-state actuator is a piezoceramic actuator.

14. The solid-state actuator as claimed in claim 1, wherein the at least one actuator layer is a piezoceramic layer.

15. The solid-state actuator as claimed in claim 2, wherein the solid-state actuator is a piezoceramic actuator.

16. The solid-state actuator as claimed in claim 2, wherein the at least one actuator layer is a piezoceramic layer.

17. The solid-state actuator as claimed in claim 3, wherein the solid-state actuator is a piezoceramic actuator.

18. The solid-state actuator as claimed in claim 3, wherein the at least one actuator layer is a piezoceramic layer.

19. The solid-state actuator as claimed in claims 3, wherein the relationship between the drive voltage and the mechanical voltage in the solid-state actuator is at least one of stored in a table and determined by a calculation.

20. The solid-state actuator as claimed in claim 3, wherein the at least one actuator layer is made of lead zirconate titanate and is additionally doped with at least one of mono-, di- and trivalent cations.

21. The solid-state actuator as claimed in claim 20, wherein the monovalent cations are implanted in the A-site of the perovskite cell and produce an acceptor doping.

22. The solid-state actuator as claimed in claim 20, wherein the di- or trivalent cations are implanted in the B-site of the perovskite cell and produce an acceptor doping.

23. The solid-state actuator as claimed in claim 2, wherein the substrate is disposed between two actuator layers.

24. The solid-state actuator as claimed in claim 3, wherein the substrate is disposed between two actuator layers.
